(19) United States
(12) Patent Application Publication
(10) Pub. No.: US 2009/0284397 A1
(43) Pub. Date: Nov. 19, 2009

(54) Keypad structure with multi-mode display function

(76) Inventors: Hsin-Chin Lee, Jhongli City (TW); Hsien-Kuo Kao, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/153,283

(22) Filed: May 16, 2008

(51) Int. Cl. H03M 11/00

(52) U.S. Cl. 341/23

(57) ABSTRACT

A keypad structure with multi-mode display function includes: a keypad layer having a plurality of key pressing positions; and a plurality of indicating unit in installed a multilayer form and under the keypad layer, and each having a light emitting element; and a light guide element corresponding to the light emitting element. A surface of the light guide element has a symbol layer, and the symbol layer includes a plurality of symbols at the key pressing positions, such that the keypad structure can display indicating symbols of different functions at a single key pressing position.

### BACKGROUND OF THE INVENTION

1. Field of the Invention

The present invention relates to a keypad structure with multi-mode display function, and more particularly to a keypad structure capable of showing different key images at a single key pressing position.

2. Description of Related Art

As science and technology advance, electronic information products are developed rapidly, but one thing remaining unchanged is that users still need to input instructions for the operation of electronic products to output user desired information according to the inputted instructions. In the present information technology era wireless communications enhance convenience to people's life by providing mobile communication products such as mobile phones, digital personal assistants (PDA) and even laptops or MP3 players, and users generally use a keyboard as an input device for controlling the electronic devices.

However, the size of electronic devices is reduced constantly, and thus the size and number of keys becomes a limitation to the manufacture of products which are light in weight. For example, MP3 provided simple functions at the beginning, and the keys adopted the design of a walkman to provide simple functions such as Play/Pause, Fast Forward, Fast Backward, and Volume, and thus the adjustment of these functions does not interfere with each other. However, more functions such as FM radio, recording, electronic book and browsing are added to the design of the MP3 players as the personal multimedia industry blooms. Obviously, the original design of a keypad no longer meets the requirements of the current needs. To allow two functions to share a key, a long/short press method is commonly used, and a 5-direction arrow keys is introduced as well. Although these designs can achieve the purpose of reducing the number of keys, yet the overall convenience of use still requires breakthroughs.

In view of the shortcomings of the conventional keyboard structure, the inventor of the present invention based on years of experience in the related field to conduct extensive researches and experiments, and finally developed a keypad structure with multi-mode display function in accordance with the present invention to overcome the foregoing shortcomings of the prior art.

### SUMMARY OF THE INVENTION

Therefore, it is a primary objective of the present invention to provide a keypad structure with multi-mode display function, and the keypad structure displays different key images on a single key pressing position to enhance the operation of the keys.

Another objective of the present invention is to provide a keypad structure with multi-mode display function, wherein the direction of symbols shown on the keys can be adjusted according to the placing angle of the keys to enhance the recognition of key functions for users.

To achieve the foregoing objectives, the present invention provides a keypad structure with multi-mode display function, comprising: a light emitting element; and a light guide element corresponding to the light emitting element, wherein a surface of the light guide element has a symbol layer, and the symbol layer has a plurality of symbols at the key pressing positions.

To achieve the foregoing objectives, the present invention provides a keypad structure with multi-mode display function, comprising:

a keypad layer, including a plurality of key pressing positions, wherein the key pressing positions are divided into first area key pressing positions and second area key pressing positions;

a first indicating unit, installed under the keypad layer, and including: a light emitting element; and a light guide element corresponding to the light emitting element, wherein a surface of the light guide element has a symbol layer, and the symbol layer has a plurality of symbols at the key pressing positions; and a second indicating unit, installed under the first indicating unit, and including a first indicating module and a second indicating module, wherein the first indicating module comprises: a first light emitting element; and a first light guide element corresponding to the first light emitting element, wherein a surface of the first light guide element has a first symbol layer, and the first symbol layer has a plurality of symbols at the first area key pressing positions; and the second indicating module comprises: a second light emitting element; and a second light guide element corresponding to the second light emitting element, wherein a surface of the second light guide element has a second symbol layer, and the second symbol layer has a plurality of symbols at the second area key pressing positions.

With the aforementioned design, the keypad structure with multi-mode display function can show different key images at a single pressing position by using multi-layer indicating structure to achieve the effect of controlling more key functions by a limited number of keys.

To make it easier for our examiner to understand the expected objectives, technical measures and effects of the present invention, we use preferred embodiments together with the attached drawings for the detailed description of the invention, but it should be pointed out that the attached drawings are provided for reference and description only, but not for limiting the present invention.

### BRIEF DESCRIPTION OF THE DRAWINGS

FIG. 1 is an exploded view of a keypad structure with multi-mode display function in accordance with a first preferred embodiment of the invention;

FIG. 2 is an exploded view of a keypad structure with multi-mode display function in accordance with a second preferred embodiment of the invention;

FIGS. 3 and 3A are schematic views of display symbols of a keypad structure with multi-mode display function in accordance with the invention;

FIG. 4 is an exploded view of a keypad structure with multi-mode display function in accordance with a third preferred embodiment of the invention;

FIGS. 5A and 5B for schematic views of display symbols in different key pressing areas of a keypad structure with multi-mode display function in accordance with the invention; and

FIG. 6 is a schematic view of changing a display symbol of a keypad structure with multi-mode display function in accordance with the invention.

### DETAILED DESCRIPTION OF THE PREFERRED EMBODIMENTS

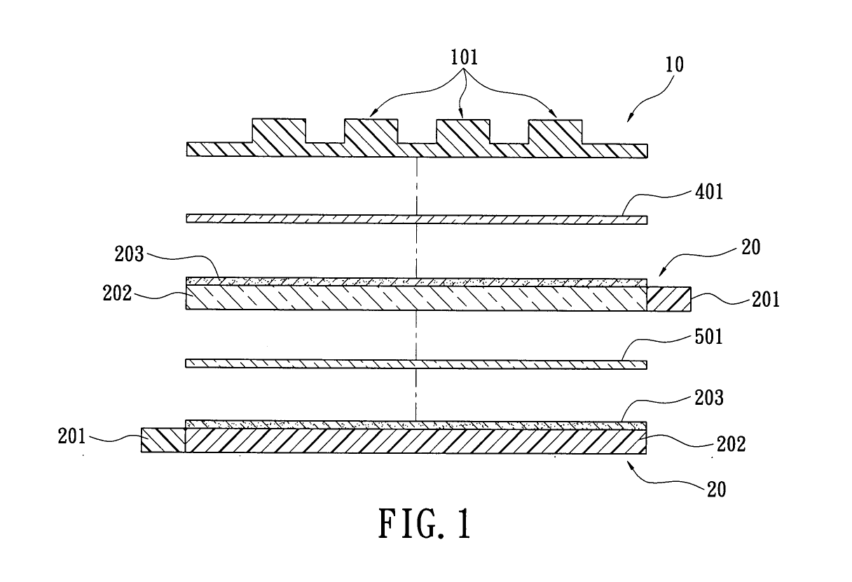

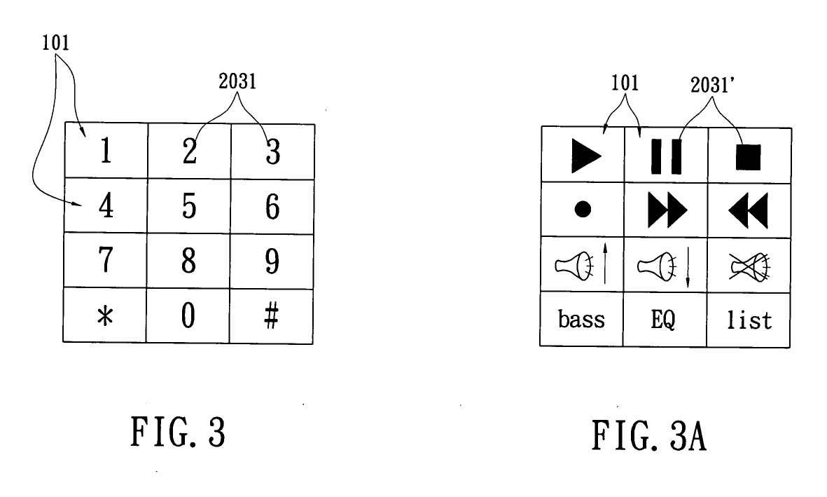

Referring to FIG. 1 for a keypad structure with multi-mode display function 1 in accordance with the present invention, different symbols can be displayed at a single key position to provide different key functions for users, and the keypad structure 1 comprises: a keypad layer 10, having a plurality of key pressing positions 101; and a plurality of indicating unit 20 installed in a multilayer form and under the keypad layer 10. In FIG. 1, the keypad structure with multi-mode display function 1 has two indicating units 20, but this number of indicating units 20 is used for illustrating the invention only, but is not intended to limit the invention. In this embodiment, the two indicating units 20 are similar structures, such as two indicating units 20 having a light emitting element 201; and a light guide element 202 corresponding to the light emitting element 201, wherein a surface of the light guide element 202 has a symbol layer 203, and the symbol layer 203 forms a plurality of indicating symbols corresponding to the key pressing positions 101; and the difference between the two indicating units 20 resides on that the symbols of the two indicating units 20 are two different indicating symbols. Referring to FIGS. 3 and 3A, the different indicating symbols of the two indicating units 20 are described as follows.

The keypad layer 10 is a physical keypad, having a plurality of key pressing positions 101 provided for users to input the key functions. The indicating units 20 installed under the keypad layer can show a plurality of indicating images corresponding to the key functions respectively at each key pressing position 101. The light emitting element 201 such as a white LED of each indicating unit 20 is installed on a lateral side of the light guide element 202, and the light guide element 202 emits a light source of the light emitting element 201 in a direction towards the keypad layer 10. The light guide element 202 provides the functions of increasing brightness, uniformity and diffusion as well as enhancing the overall quality of luminance and viewing angle of the keypad structure with multi-mode display function 1. Further, a surface of the light guide element 202 has a symbol layer 203, and the light emitted by the light emitting element 201 goes through the light guide and scattering functions of the light guide element 202 to form different images, symbols or alphabets corresponding to different key functions on the symbol layer 203.

During an application, users can select using a desired indicating unit 20 to show the required key function on the keypad layer 10 by means of a switch design. Returning to FIG. 1 and referring to FIGS. 3 and 3A at the same time, if a user selects a switch for dialing a phone call, the light emitting element 201 of the upper indicating unit 20 will be electrically connected to emit light. After the light is guided, refracted, reflected or gone through other optical operations by the light guide element 202, the symbol layer 203 shows the function of each key. In FIG. 3, the symbol layer 203 of the upper indicating unit 20 has number symbols 2031, and each number symbol 2031 corresponds to each key pressing position 101 of the keypad layer 10, so that users can dial a phone call according to the indication given by the number symbol 2031. Similarly, if a user turns on a music function, the light emitting element 201 of the lower indicating unit 20 will be electrically connected to power source in order to emit light, and the light will be guided, refracted, reflected or other optical operations by the light guide element 202 to display the function of each key through the symbol layer 203. In FIG. 3A, the symbol layer 203 of the lower indicating unit 20 has music playing symbols 2031′, and each music playing symbol 2031′ corresponds to each key pressing position 101 of the keypad layer 10, so that users can control the electronic device to play sounds according to the indication of the music playing symbol 2031′. Further, the symbol layer 203 of different indicating units 20 is preferably formed by color inks of different colors, and the symbols in different colors can be used for indicating different key functions, for example the number symbols 2031 can be in blue color and the music playing symbols 2031′ can be in yellow color. Alternatively, the symbol layer is made from transparent inks or light transflective structures.

In addition, a polarization unit 401 is installed between the keypad layer 10 and the indicating units 20, and the polarization unit 401 can be a polarizer, a ¼λ (i.e., ¼ wavelength) wave-plate, or a combination of a polarizer and one ¼λ wave-plate. The polarization unit 401 is provided for filtering the light such as the sunlight passing through the front of the keypad layer 10 to achieve the effect of preventing glares, so as to enhance the contrast of the symbols. Further, a grating unit 501 is installed between two adjacent indicating units 20, and the grating unit 501 is a grating plate or a polarizer for isolating the upper and lower images and preventing the lower symbols from being affected by the structure of the upper indicating units 20 or the colors of their symbol layer 203 when the lower symbols are shown. When the light source is turned on, the grating unit 501 can block the light, so that the internal symbols cannot be seen from outside the keypad structure. The upper symbol layer 203 is preferably transparent, so that it will not affect the display of the lower indicating symbols.

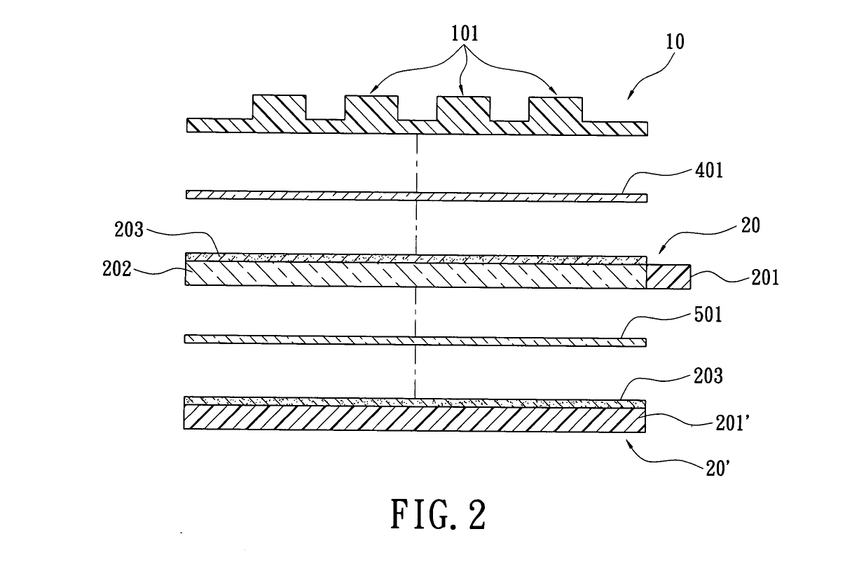

Referring to FIG. 2 for a second preferred embodiment of the present invention, the difference between this preferred embodiment and the first preferred embodiment resides on that the light emitting element 201′ of the lower indicating unit 20′ is an electro luminescent (EL) element, which is a light emitting unit that can be installed directly under the symbol layer 203. If the light emitting element 201′ is electrically connected to emit light, the symbol layer 203 can be used directly for displaying different key functions at each key pressing position 101. It is noteworthy to point out that the number of indicating units 20 is not limited to those described in the foregoing preferred embodiments only, but can be adjusted according to practical applications.

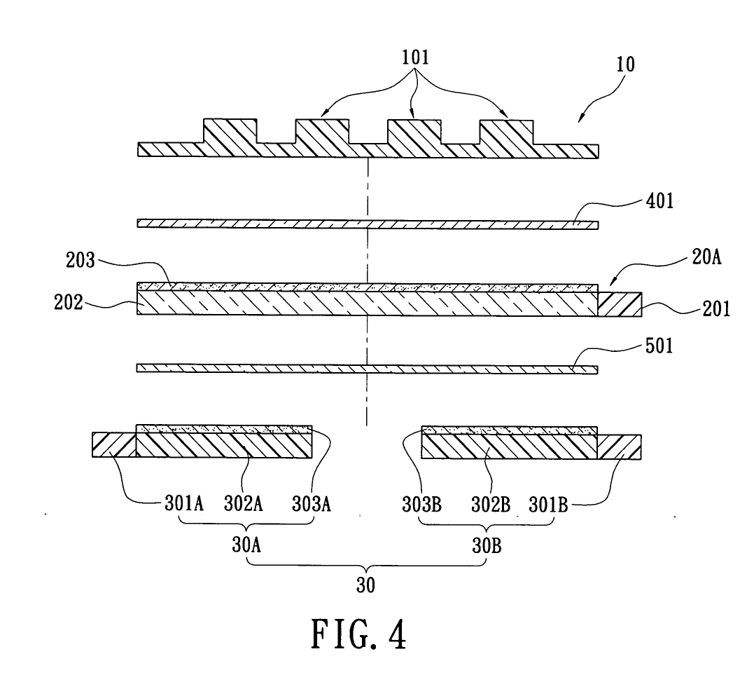

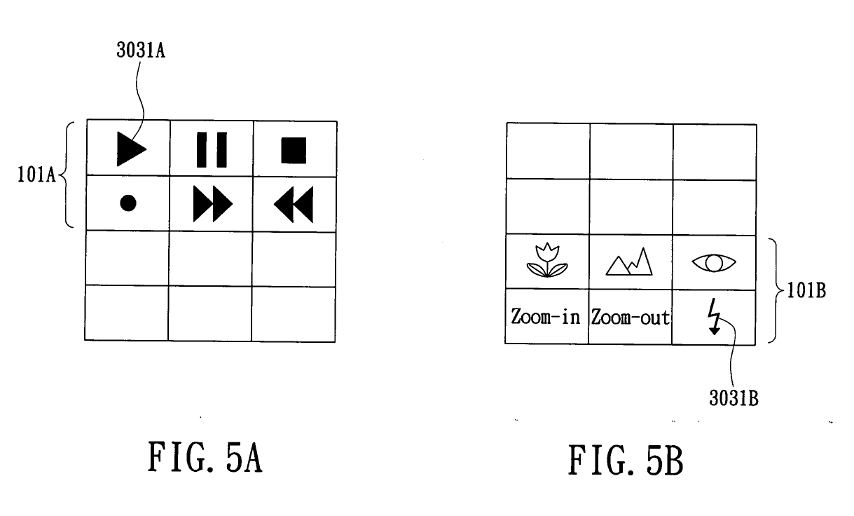

Further, the present invention also provides another embodiment of the keypad structure with multi-mode display function 1, which is a structure comprising a plurality of indicating modules at different key pressing positions for showing different indicating symbols in different key pressing positions 101 of the keypad layer 10. Referring to FIG. 4 for a third preferred embodiment of the present invention, this embodiment comprises a keypad layer 10, having a plurality of key pressing positions 101, wherein the key pressing positions 101 are divided into a first area of key pressing positions 101A and a second area of key pressing positions 101B (as shown in FIGS. 5A and 5B); a first indicating unit 20A installed under the keypad layer 10, and comprising: a light emitting element 201; and a light guide element 202 corresponding to the light emitting element 201, wherein a surface of the light guide element 202 has a symbol layer 203, and the symbol layer 203 has a plurality of symbols at the key pressing positions, and the first indicating unit 20A has the same characteristics as the indicating unit 20 as described in the first preferred embodiment, and thus will not be described here again. The difference between this preferred embodiment and the first preferred embodiment resides on that the second indicating unit 30 installed under the first indicating unit 20A of this embodiment comprises a first indicating module 30A and a second indicating module 30B. The two modules are described in detail as follows. The first indicating module 30A comprises a first light emitting element 301A and a first light guide element 302A corresponding to the first light emitting element 301A, wherein a surface of the first light guide element 302A has a first symbol layer 303A, and the first symbol layer 303A has a plurality of symbols corresponding to the first area of key pressing positions 101A. The second indicating module 30B comprises a second light emitting element 301B and a second light guide element 302B corresponding to the second light emitting element 301B, wherein a surface of the second light guide element 302B has a second symbol layer 303B, and the second symbol layer 303B has a plurality of symbols corresponding to the second area of key pressing positions 101B. If a user turns on the first indicating unit 20A, the keypad structure with multi-mode display function 1 will show number symbols as shown in FIG. 3, and each number symbol 2031 corresponds to each key pressing position 101 of the keypad layer 10, so that the user can dial a phone number based on the indication of the number symbols 2031. If the user turns on the first indicating module 30A of the second indicating unit 30, the first indicating module 30A will show a multimedia control symbol 3031A at the first area of key pressing position 101A (with two rows of key pressing positions 101 as shown in FIG. 5), but the lower two rows of second area key pressing positions 101B will not be shown. Similarly, if the user turns on the second indicating module 30B of the second indicating unit 30, the second indicating module 30B will show a photograph control symbol 3031B corresponding to the second area of key pressing positions 101B, so that the user can use the photograph control symbol 3031B to control the electronic device for the function of taking pictures. Therefore, the keypad layer 10 provides a more effective way of installing the keys, and the keypad device can have more key functions with less layers of indicating units 20. In this embodiment, other component modules such as a grating unit 501 are the same as those described in the first preferred embodiment, and thus will not be described here again.

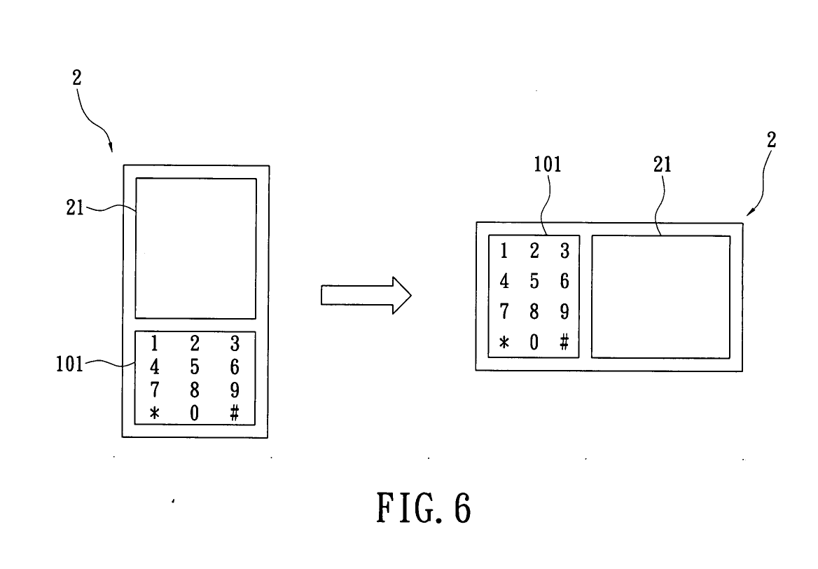

The keypad structure with multi-mode display function 1 of the invention can operate with a device such as a liquid switch for setting a multiple of functions. In FIG. 6, the mobile phone 2 includes a display device 21 and a keypad structure with multi-mode display function 1 of the invention, and the keypad structure with multi-mode display function 1 comes with portrait key symbols (which can be indicated by the upper indicating unit 20 of the first preferred embodiment) and a landscape key symbol (which can be indicated by the lower indicating unit 20 of the first preferred embodiment). If the mobile phone 2 is erected, the liquid switch will electrically conduct the upper indicating unit 20, such that the key pressing positions 101 will show the portrait key symbols. If the mobile phone 2 is placed transversally, then the liquid switch will electrically conduct the lower indicating unit 20, such that the key pressing positions 101 will show landscape key symbols. The foregoing arrangement allows users to identify the functions of each key pressing position 101 more clearly. However, the embodiments described above are used for illustrating the present invention only, but not intended to limit the invention to the application of a particular device such as a mobile phone only. On the other hand, the present invention can also be applied extensively to any electronic device having keys.

In summation of the description above, the present invention has the following advantages:

1. The keypad structure with multi-mode display function 1 of the invention provides a choice of keys of various functions for electronic devices, and shows different key functions according to user requirements, so that users can identify the function of each key clearly.

2. The keypad structure of the invention is composed of indicating units 20 installed in a multilayer form, so that the keypad structure with multi-mode display function 1 can show the indicating symbols for different functions at a single key pressing position, and the keys can be organized in a neater manner.

3. The keypad structure of the invention is composed of indicating units 20 installed in a multilayer form to achieve the effect of adjusting the direction of the key symbols, so as to provide a better viewing angle and a more user-friendly operation to the electronic device.

Although the present invention has been described with reference to the preferred embodiments thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A keypad structure with multi-mode display function, comprising:
a keypad layer, including a plurality of key pressing positions; and
a plurality of multi-layer indicating units installed under the keypad layer, each indicating unit comprising:
a light emitting element; and
a light guide element corresponding to the light emitting element, wherein a surface of the light guide element has a symbol layer, and the symbol layer has a plurality of symbols corresponding to the key pressing positions.

2. The keypad structure with multi-mode display function as in claim 1, further comprising a polarizer, a ¼ wavelength wave-plate or a combination of the polarizer and the ¼ wavelength wave-plate installed between the keypad layer and the indicating units.

3. The keypad structure with multi-mode display function as in claim 1, further comprising a grating unit disposed between the two adjacent indicating units.

4. The keypad structure with multi-mode display function as in claim 1, wherein the symbol layer is a transparent ink.

5. The keypad structure with multi-mode display function as in claim 1, wherein the light emitting element is a light emitting diode (LED) or an electro luminescent (EL) element.

6. A keypad structure with multi-mode display function, comprising:
a keypad layer, including a plurality of key pressing positions, the key pressing positions being divided into a first area of key pressing positions and a second area of key pressing positions;
a first indicating unit, disposed under the keypad layer, including:
a light emitting element;
a light guide element corresponding to the light emitting element, a surface of the light guide element having a symbol layer, and the symbol layer having a plurality of symbols corresponding to the key pressing positions;
a second indicating unit, disposed under the first indicating unit, the second indicating unit including a first indicating module and a second indicating module;
the first indicating module comprising:
a first light emitting element and
a first light guide element corresponding to the first light emitting element, a surface of the first light guide element having a first symbol layer, and the first symbol layer having a plurality of symbols corresponding to the first area of key pressing positions;
the second indicating module comprising:
a second light emitting element and
a second light guide element corresponding to the second light emitting element, a surface of the second light guide element having a second symbol layer, and the second symbol layer having a plurality of symbols corresponding to the second area of key pressing positions.

7. The keypad structure with multi-mode display function as in claim 6, further comprising a polarizer, a ¼ wavelength wave-plate or a combination of the polarizer and the ¼ wavelength wave-plate installed between the keypad layer and the first indicating unit.

8. The keypad structure with multi-mode display function as in claim 6, further comprising a grating unit installed between the first indicating unit and the second indicating unit.

9. The keypad structure with multi-mode display function as in claim 6, wherein the symbol layer, the first symbol layer and the second symbol layer are transparent inks or light transflective structures.

10. The keypad structure with multi-mode display function as in claim 6, wherein the light emitting element, the first light emitting element and the second light emitting element are light emitting diodes (LED) or electro luminescent elements.
